(19) United States
(12) Patent Application Publication
(10) Pub. No.: US 2025/0323331 A1
(43) Pub. Date: Oct. 16, 2025

(54) Battery Swelling Force Measurment Apparatus

(71) Applicants: Hyundai Motor Company, Seoul (KR); Kia Corporation, Seoul (KR); Kookmin University Industry Academy Cooperation Foundation, Seoul (KR)

(72) Inventors: Jang Hyeon Lee, Suwon-si (KR); Il Seon Yoo, Suwon-Si (KR); Hyun Soo Kim, Suwon-Si (KR); Dong Gu Kim, Suwon-Si (KR); Dae Sung Kwon, Seoul (KR); Si Hyung Lim, Seoul (KR); Soon Ho Hwang, Goyang-Si (KR)

(21) Appl. No.: 18/965,183

(22) Filed: Dec. 2, 2024

(30) Foreign Application Priority Data
Apr. 15, 2024 (KR) 10-2024-0049767

(51) Int. Cl. H01M 10/42; G01L 1/26; G01R 31/389; H01M 10/48

(52) U.S. Cl. CPC H01M 10/4285; G01L 1/26; G01R 31/389; H01M 10/486

(57) ABSTRACT

An apparatus for monitoring battery swelling may comprise first sensors configured to be in contact with a battery cell and measure, based on a swelling force of the battery cell, a change in resistance of the battery cell, heat transfer plates configured to be in contact with outer surfaces of the first sensors, second sensors configured to be in contact with outer surfaces of the heat transfer plates and measure, based on a temperature of the battery cell, a change in the resistance, a pair of end plates configured to be in contact with outer surfaces of the second sensors and fasten, based on a fastening pressure, the battery cell, the first sensors, the heat transfer plates, and the second sensors, and a controller configured to adjust, based on an output signal of a sensor of the second sensors, an output signal of a corresponding sensor of the first sensors.

### CROSS-REFERENCE TO RELATED APPLICATION

This application claims under 35 U.S.C. § 119(a) the benefit of priority to Korean Patent Application No. 10-2024-0049767 filed on Feb. Apr. 15, 2024, the entire contents of which are incorporated herein by reference.

### TECHNICAL FIELD

The present disclosure relates to a battery swelling force measurement apparatus. More particularly, it relates to a battery swelling force measurement apparatus that enables temperature compensation of the swelling force of a battery measured by a force sensor in consideration of the temperature of the battery.

### BACKGROUND

The matters described in this Background section are only for enhancement of understanding of the background of the disclosure, and should not be taken as acknowledgement that they correspond to prior art already known to those skilled in the art.

Lithium-ion batteries (LIB) have high volumetric energy density and excellent charging efficiency, and thus, may be used among secondary batteries and useful as batteries for mobile phones, batteries for electric vehicles, and the like.

However, the lithium-ion batteries have the possibility of explosion and fire due to various reasons, such as incorporation of foreign substances, overcharge, overdischarge, heating, shock, and internal reaction, and extinguishing a fire in a lithium-ion battery is known to be more difficult than a general fire.

Therefore, in order to prevent the risk of explosion and fire of a lithium-ion battery, it is useful to monitor the swelling state of the lithium-ion battery.

For reference, swelling of the battery refers to a phenomenon in which a battery cell swells due to pressure when a lithium ion electrolyte evaporates.

However, battery management systems (BMSs) have the disadvantage of not being able to directly detect the swelling phenomenon of a battery.

Methods of measuring swelling of batteries may include strain measurement methods, which are indirect measurement methods, and a force measurement method, which is a direct measurement method.

The strain measurement methods may include dilatometry, a surface strain measurement method, an internal strain measurement method, and the like.

Dilatometry is a method of measuring swelling displacement by attaching a dilatometer to the surface of a battery, and thus, it may be difficult to directly measure the swelling force of the battery, and further there is a limitation in measuring the accurate swelling displacement of the battery in the state in which the battery is already pre-loaded by end plates or pressing jigs.

Dilatometry, the surface strain measurement method, the internal strain measurement method may only measure swelling displacement in one direction, may be inaccurate because temperature compensation of a measurement signal is not achieved in consideration of the temperature of the battery, and have limitations in accurately measuring whether the battery is in a normal or faulty state because the battery may expand even in normal conditions.

The force measurement method, which is a direct measurement method, may accurately measure the swelling force of a battery mainly using a load cell, but may have limitations in building an actual measurement system because equipment used in the force measurement has a complicated structure and includes a fixing device, such as a separate jig, and thus occupies a large volume.

### SUMMARY

According to the present disclosure, an apparatus for monitoring battery swelling, the apparatus may comprise a first plurality of sensors configured to be in contact with two sides of a battery cell and measure, based on a swelling force of the battery cell, a change in resistance of the battery cell, heat transfer plates configured to be in contact with outer surfaces of the first plurality of sensors, a second plurality of sensors configured to be in contact with outer surfaces of the heat transfer plates and measure, based on a temperature of the battery cell, a change in the resistance, a pair of end plates configured to be in contact with outer surfaces of the second plurality of sensors and fasten, based on a designated fastening pressure, the battery cell, the first plurality of sensors, the heat transfer plates, and the second plurality of sensors, and a controller configured to adjust, based on an output signal of a sensor of the second plurality of sensors, an output signal of a corresponding sensor of the first plurality of sensors.

The apparatus, wherein each sensor of the second plurality of sensors may comprise a conductive sensing plate formed of a pressure resistant material, a first electrode provided in a first structure and configured to be in contact with one surface of the conductive sensing plate, wherein a first electrode line having a first predetermined length is integrally connected in the first structure, a second electrode provided in a second structure and configured to be in contact with a remaining surface of the conductive sensing plate, wherein a second electrode line having a second predetermined length is integrally connected in the second structure, and an insulating protective layer applied to outer surfaces of the first electrode and the first electrode line, and outer surfaces of the second electrode and the second electrode line.

The apparatus, wherein a support layer is configured to be in non-contact with the conductive sensing plate, the first electrode, and the second electrode, wherein the support layer is supported by an inner surface of each of the pair of end plates, and wherein the support layer extends from a periphery of the insulating protective layer.

The apparatus, wherein a sensing plate displacement space is configured to be between the conductive sensing plate and the second electrode by stacking a ring-shaped adhesive spacer between the conductive sensing plate and the second electrode.

The apparatus, wherein a contact avoidance hole for non-contact with the conductive sensing plate of each of the second plurality of sensors is formed through a corresponding one of the pair of end plates.

The apparatus, wherein a guide groove is formed on an inner surface of each of the pair of end plates to guide first electrode lines of a corresponding sensor of the first plurality of sensors to outside of the pair of end plates, and guide second electrode lines of a corresponding sensor of the second plurality of sensors to outside of the pair of end plates.

The apparatus, wherein bolt fastening holes are formed at respective corners of each of the pair of end plates to fasten the pair of end plates to each other with bolts.

The apparatus, wherein springs are loaded on peripheries of the bolts and disposed between the pair of end plates to elastically support the pair of end plates.

The apparatus, wherein the controller is configured to adjust, based on a difference between a first resistance change signal and a second resistance change signal, the output signal of the corresponding sensor of the first plurality of sensors, wherein the second resistance change signal is based on a change in the temperature of the battery cell, and wherein the first resistance change signal is based on a change in the swelling force of the battery cell measured by the corresponding sensor of the first plurality of sensors.

The apparatus, wherein a support block is configured to support, based on a plurality of battery cells being stacked, peripheries of the plurality of battery cells, and wherein the support block is disposed between the pair of end plates.

The apparatus, wherein the support block is configured with a battery cell accommodation space that extends through a center of the support block from side to side, wherein bolt fastening holes are formed at respective corners of surfaces of the support block, and wherein the support block is fastened to the pair of end plates with bolts placed in the bolt fastening holes.

The apparatus, wherein a guide block having guide holes is configured to guide first electrode lines of the first plurality of sensors to outside of the pair of end plates and guide second electrode lines of the second plurality of sensors to outside of the pair of end plates, and wherein the guide block is attached to a front part of the support block.

According to the present disclosure, a method performed by an apparatus for monitoring battery swelling, the method may comprise based on a designated fastening pressure, fastening, by a pair of end plates of the apparatus, a battery cell, a first plurality of sensors of the apparatus, heat transfer plates of the apparatus, and a second plurality of sensors of the apparatus, and based on the fastening and a swelling force of the battery cell, measuring, by the first plurality of sensors, a first change in resistance of the battery cell, measuring, by the second plurality of sensors and based on a temperature of the battery cell, a second change in the resistance, wherein the second plurality of sensors are in contact with outer surfaces of the heat transfer plates that are in contact with outer surfaces of the first plurality of sensors, and adjusting, by a controller of the apparatus, based on the first change and the second change, an output signal of a sensor of the first plurality of sensors.

The method, wherein the fastening may comprise placing bolts in bolt fastening holes formed at respective corners of each of the pair of end plates, and elastically supporting, by springs loaded on peripheries of the bolts and disposed between the pair of end plates, the pair of end plates.

The method, wherein the adjusting the output signal of the sensor of the first plurality of sensors may comprise subtracting the second change from the first change, and adjusting, based on the subtracting, the output signal of the sensor of the first plurality of sensors.

The method may further comprise transferring, by the heat transfer plates, heat generated from a surface of the battery cell to the second plurality of sensors. The method, wherein the pair of end plates comprise contact avoidance holes so that contact surface areas between the second plurality of sensors and the pair of end plates are reduced.

The method, wherein the first plurality of sensors and the second plurality of sensors are force-sensitive resistors configured as thin films attachable to surfaces of the battery cell.

The method may further comprise performing, based on the output signal of the sensor of the first plurality of sensors, real-time monitoring of the battery swelling.

The method may further comprise displaying, by the controller, at least one of the output signal of the sensor of the first plurality of sensors, or an output signal of a sensor of the second plurality of sensors.

### BRIEF DESCRIPTION OF THE DRAWINGS

The above and other features of the present disclosure will now be described in detail with reference to certain examples thereof illustrated in the accompanying drawings which are given hereinbelow by way of illustration only, and thus are not limitative of the present disclosure, and wherein:

FIG. 1 shows an example of the assembled state of a battery swelling force measurement apparatus according to one example of the present disclosure;

FIG. 2 shows an example of the disassembled state of the battery swelling force measurement apparatus according to one example of the present disclosure;

FIG. 3 shows an example of the assembled state of the battery swelling force measurement apparatus according to one example of the present disclosure;

FIG. 4 shows an example of a battery swelling force measurement apparatus according to another example of the present disclosure;

FIG. 5 shows an example of a force sensor of the battery swelling force measurement apparatus according to the present disclosure;

FIG. 6 shows an example of the force sensor of the battery swelling force measurement apparatus according to the present disclosure;

FIG. 7 shows an example of the operation of a first force sensor (FSR), which is a force sensor of the battery swelling force measurement apparatus according to the present disclosure, to measure the swelling force of a battery cell;

FIG. 8 shows an example of a swelling force output signal of the first force sensitive resistor (FSR), which is the force sensor of the battery swelling force measurement apparatus according to the present disclosure; and

FIG. 9 shows an example in which the swelling force output signal of the first force sensor, which is the force sensor of the battery swelling force measurement apparatus according to the present disclosure, is temperature-compensated by a temperature output signal of a second force sensor.

It should be understood that the appended drawings are not necessarily to scale, presenting a somewhat simplified representation of various preferred features illustrative of the basic principles of the disclosure. The specific design features of the present disclosure as disclosed herein, including, for example, specific dimensions, orientations, locations, and shapes, will be determined in part by the particular intended application and use environment.

In the figures, reference numbers refer to the same or equivalent parts of the present disclosure throughout the several figures of the drawing.

### DETAILED DESCRIPTION

Specific structural or functional descriptions in examples of the present disclosure set forth in the description which follows will be exemplarily given to describe the examples of the present disclosure, and the present disclosure may be embodied in many alternative forms. Further, it will be understood that the present disclosure should not be construed as being limited to the examples set forth herein, and the examples of the present disclosure are provided only to completely disclose the disclosure and cover modifications, equivalents or alternatives which come within the scope and technical range of the disclosure.

In the following description of the examples, terms, such as “first” and “second”, are used only to describe various elements, and these elements should not be construed as being limited by these terms. These terms are used only to distinguish one element from other elements. For example, a first element described hereinafter may be termed a second element, and similarly, a second element described hereinafter may be termed a first element, without departing from the scope of the disclosure.

When an element or layer is referred to as being “connected to” or “coupled to” another element or layer, it may be directly connected or coupled to the other element or layer, or intervening elements or layers may be present. In contrast, when an element or layer is referred to as being “directly connected to” or “directly coupled to” another element or layer, there may be no intervening elements or layers present. Other words used to describe relationships between elements should be interpreted in a like fashion, e.g., “between” versus “directly between,” “adjacent” versus “directly adjacent,” etc.

Wherever possible, the same reference numbers will be used throughout the following description and the drawings to refer to the same or like parts. The terminology used herein is for the purpose of describing particular examples only and is not intended to be limiting. As used herein, singular forms may be intended to include plural forms as well, unless the context clearly indicates otherwise. The terms “comprises,” “comprising,” “including,” and “having” are inclusive and therefore specify the presence of stated features, integers, operations, operations, elements, components, and/or combinations thereof, but do not preclude the presence or addition of one or more other features, integers, operations, operations, elements, components, and/or combinations thereof.

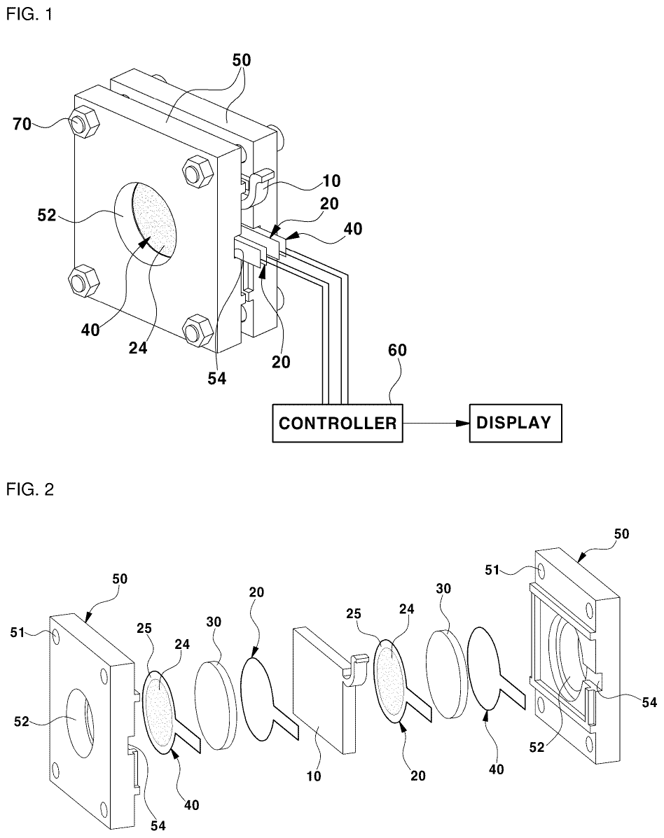

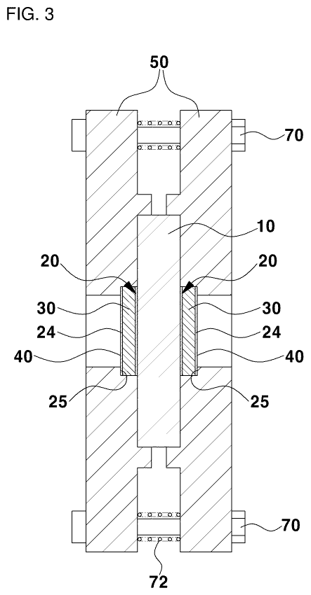

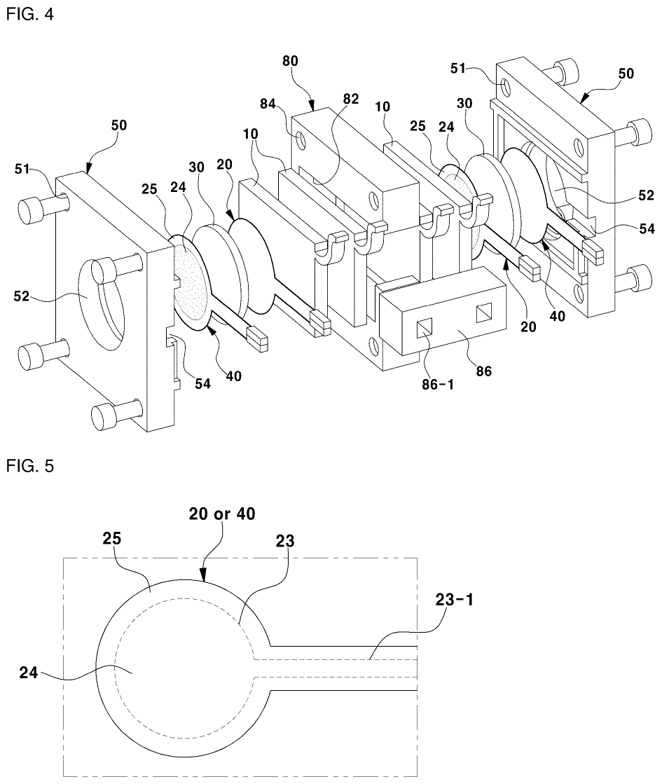

FIGS. 1, 2 and 3 are views showing a battery swelling force measurement apparatus according to one example of the present disclosure, and in each view, reference numeral 10 indicates a battery cell.

The battery swelling force may be a physical pressure (e.g., exerted by gases or electrolytes) within a battery cell that causes it to expand. The battery swelling force may be caused by internal reactions, especially in faulty or damaged cells, leading to the physical swelling of the battery.

To quantify the battery swelling force, for example, the following methods and techniques may be used. Force Sensing-Resistor (hereinafter referred to as “FSR”) sensors may be attached to the battery's surface to measure changes in resistance as force increases due to swelling. The resistance change is then translated into force (e.g., Newtons) using a calibration curve. Pressure-sensitive films or electronic pressure sensors may be placed between the battery and a rigid surface. These sensors measure the pressure (e.g., Pascals or psi) exerted as the battery swells. Displacement sensors may be used to measure the physical expansion of the battery (e.g., millimeters or microns). The displacement data may be combined with material properties to determine the resulting force or pressure. Load cells may be used to directly measure the force exerted by a swelling battery. The load cell may be placed in contact with the battery, and as the battery swells, the force applied is measured (e.g., in Newtons). Strain gauges may be attached to a structure holding the battery. As the battery swells, the structure may deform slightly, and the strain gauge may measure this deformation. This strain data may be used to determine the force exerted. Finite Element Analysis (FEA) simulations may be used to estimate the force. By modeling the battery materials and their swelling behavior under various conditions, the swelling force may be predicted and quantified.

A first FSR 20, a heat transfer plate 30, a second FSR 40, and an end plate 50 are sequentially stacked on each of both sides of the battery cell 10.

Since the first FSR 20, the heat transfer plate 30, the second FSR 40, and the end plate 50 are sequentially stacked on each of both sides of the battery cell 10, these elements may be provided as pairs.

The first FSR 20 is a type of force sensor, and is configured to be in close contact with each of both surfaces of the battery cell 10 to measure a change in swelling force of the battery cell 10.

Accordingly, the first FSR 20 may measure the change in swelling force of the battery cell 10, i.e., a change in swelling force of the battery cell 10 due to swelling, as a change in resistance, and may output a measured resistance change signal to a controller 60 as an output signal.

The heat transfer plate 30 may be made of a copper alloy material having excellent heat transfer rate and low thermal deformation to transfer heat generated from the surface of the battery cell 10 to the second FSR 40 as much as possible.

Accordingly, the inner surface of the heat transfer plate 30 is in close contact with the first FSR 20, and the outer surface of the heat transfer plate 30 is in close contact with the second FSR 40, thereby being capable of transferring heat generated from the surface of the battery cell 10 to the second FSR 40.

The second FSR 40 is a type of force sensor, and is configured to be in close contact with the outer surface of the heat transfer plate 30 to measure a change in temperature of the battery cell 10.

Accordingly, if heat generated from the battery cell 10 is transferred to the second FSR 40 through the heat transfer plate 30, the second FSR 40 may measure a change in resistance of the battery cell 10 depending on the change in temperature, and may output a measured resistance change signal to the controller 60 as an output signal.

The end plate 50 is in close contact with the outer surface of the second FSR 40, and is configured to fasten the battery cell 10, and the first FSR 20, the heat transfer plate 30, and the second FSR 40 sequentially stacked on each of both sides of the battery cell 10 with a predetermined fastening pressure.

For this purpose, bolt fastening holes 51 are formed at respective corners of the end plates 50 to fasten a pair of end plates 50 facing each other with bolts 70.

Accordingly, in the state in which the battery cell 10, and the first FSRs 20, the heat transfer plates 30, and the second FSRs 40, which are sequentially stacked on both sides of the battery cell 10, are disposed between the pair of end plates 50, the battery cell 10, and the first FSRs 20, the heat transfer plates 30, and the second FSRs 40 may be fastened to each other with a designated fastening pressure by inserting the bolts 70 into the bolt fastening holes 51 of one of the end plates 50 and then fastening the bolts 70 to the bolt fastening holes 51 of the other of the end plates 50.

If the pair of end plates 50 is fastened to each other with the bolts 70, an imbalance in initial fastening pressure to fasten the battery cell 10, the first FSRs 20, the heat transfer plates 30, and the second FSRs 40 may occur, and the final coupling force of the end plates 50 may be excessive beyond a certain level and cause damage to the first FSRs 20, the heat transfer plates 30, and the second FSRs 40.

To solve this problem, the springs 72, which are loaded on the peripheries of the bolts 70, may be disposed between the pair of end plates 50 to elastically support the end plates 50.

Accordingly, if the pair of end plates 50 is fastened to each other with the bolts 70, the springs 72 may be compressed while buffering the fastening pressure by the end plates 50, thereby being capable of distributing the initial fastening pressure of the end plates 50 to fasten the battery cell 10, the first FSRs 20, the heat transfer plates 30, and the second FSRs 40 in a balanced manner, and preventing the final coupling force of the end plates 50 from exceeding the certain level.

The controller 60 is configured to correct the resistance change signal measured depending on the change in swelling force of the battery cell 10, which is the output signal of the first FSR 20, based on the resistance change signal measured depending on the change in temperature of the battery cell 10, which is the output signal of the second FSR 40.

For example, considering that a swelling force output signal measured by the first FSR 10 is distorted to generate an error with an actual swelling force due to the change in temperature of the battery cell 10, the controller 60 may be configured to perform correction by subtracting the resistance change signal depending on the change in temperature of the battery cell 10 measured by the second FSR 40 from the resistance change signal depending on the change in swelling force of the battery cell 10 measured by the first FSR 20.

Hereinafter, the specific configuration of the first FSR 20 and the second FSR 40 will be described.

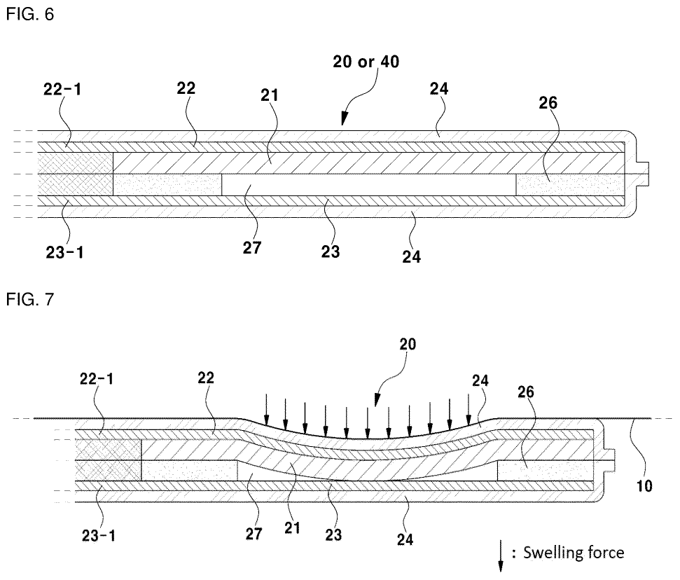

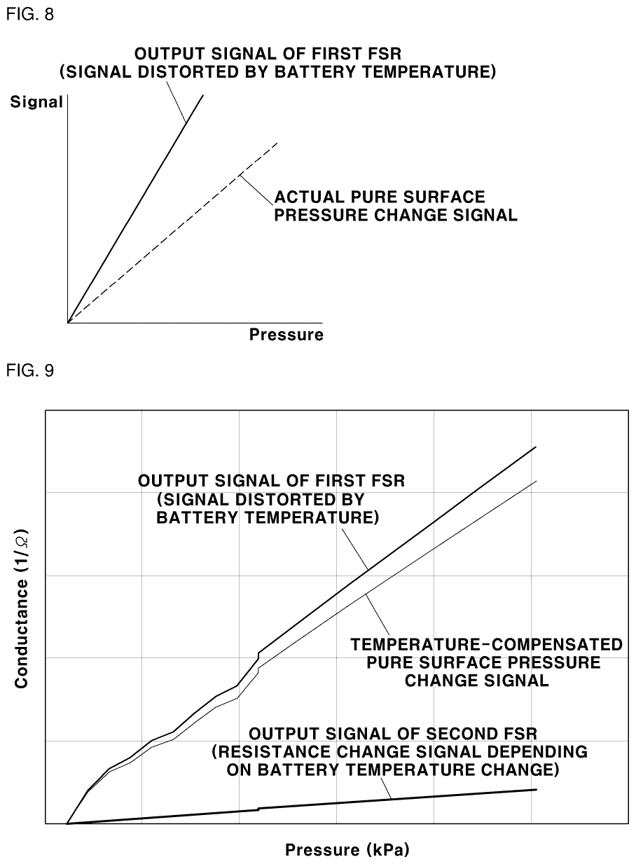

FIGS. 5 and 6 are a plan view and a cross-sectional view showing a force sensor of the battery swelling force measurement apparatus according to the present disclosure, respectively.

The first FSR 20 is used to measure a change in swelling force of the battery cell 10, i.e., a change in swelling force of the battery cell 10 due to swelling, and the second FSR 40 is used to measure a change in temperature of the battery cell 10. However, pressure resistance type force sensors having the same configuration are employed as the first FSR 20 and the second FSR 40.

For this purpose, each of the first FSR 20 and the second FSR 40 may include, as shown in FIGS. 5 and 6, a conductive sensing plate 21 formed of a pressure resistant material, a first electrode 22 provided with a structure in which a first electrode line 22-1 having a predetermined length is integrally connected, and configured to be in close contact with one surface of the sensing plate 21, a second electrode 23 provided with a structure in which a second electrode line 23-1 having a predetermined length is integrally connected, and configured to be in close contact with the other surface of the sensing plate 21, and an insulating protective layer 24 applied to the outer surfaces of the first electrode 22 and the first electrode line 22-1 and the outer surfaces of the second electrode 23 and the second electrode line 23-1.

Particularly, a support layer 25, which is not in contact with the sensing plate 21, the first electrode 22, and the second electrode 23 and is closely supported by the inner surface of the end plate 50, integrally extends from the periphery of the insulating protective layer 24, and thereby, the size of the insulating protective layer 24 may be further increased by the support layer 25.

Accordingly, if the insulating protective layer 24 is applied to the outer surfaces of the first electrode 22 and the second electrode 23 in the state in which the first electrode 22 and the second electrode 23 are stacked with the sensing plate 21 interposed therebetween, the support layer 25 integrally formed around the insulating protective layer 24 is in a non-contact state with the sensing plate 21, the first electrode 22, and the second electrode 23, and as a result, even though external force is applied to the support layer 25, the external force is not transmitted to the sensing plate 21, the first electrode 22, and the second electrode 23.

In addition or alternative, a ring-shaped adhesive spacer 26 may be stacked between the sensing plate 21 and the second electrode 23 to define a sensing plate displacement space 27 between the sensing plate 21 and the second electrode 23.

A contact avoidance hole 52 for non-contact with the sensing plate 21, the first electrode 22, and the second electrode 23 of the second FSR 40 is formed through the end plate 50, and a guide groove 54 is formed on the inner surface of the end plate 50 to lead the electrode lines 22-1 and 23-1 of the first FSR 20 and the second FSR 40 to the outside.

Here, the contact avoidance hole 52 is formed to have a size almost similar to the size of the second electrode 23 and the insulating protective layer 24 applied to the second electrode 23.

Accordingly, if the battery cell 10, and the first FSRs 20, the heat transfer plates 30, and the second FSRs 40 sequentially stacked on both sides of the battery cell 10 are fastened by the pair of end plates 50, the insulating protective layers 24 applied to the second electrodes 23 of the second FSRs 40 are exposed to the outside through the contact avoidance holes 52 of the end plates 50, and only the support layers 25 formed on the peripheries of the insulating layers 24 of the second electrodes 23 may be supported in close contact with the inner surfaces of the end plates 50.

Since the sensing plates 21, the first electrodes 22, and the second electrodes 23 of the second FSRs 40 are in a state of non-contact with the end plates 50, no pressure, such as external force or swelling force of the battery cell 10, is applied to the sensing plates 21 of the second FSRs 40.

Even if no pressure, such as external force or swelling force of the battery cell 10, is transmitted to the sensing plates 21 of the second FSRs 40, if heat generated from the battery cell 10 is transmitted to the second FSRs 40 through the heat transfer plates 30, the resistance of the sensing plates 21 of the second FSRs 40 is changed, and ultimately, the second FSRs 40, which are the same force sensors as the first FSRs 20, may be used to output a resistance change signal due to the change in temperature of the battery cell 10.

Meanwhile, if a plurality of battery cells 10 is stacked, a support block 80, which support the peripheries of the plurality of battery cells 10, may be further disposed between the pair of end plates 50.

For this purpose, the support block 80 may be provided in a structure in which a battery cell accommodation space 82 is formed to penetrate the center of the support block 80 from side to side, and bolt fastening holes 84 are formed at respective corners of both surfaces of the support block 80 to be fastened to the end plates 50 with the bolts 70, in order to fix and align the plurality of battery cells 10.

Further, a guide block 86 having guide holes 86-1 configured to withdraw the electrodes lines 22-1 and 23-1 of the first FSRs 20 and the second FSRs 40 to the outside may be attached to the front part of the support block 80.

Hereinafter, the measurement operation of the battery swelling force measurement apparatus according to the present disclosure configured as described above will be described.

FIG. 7 shows an example of the operation of the first force sensor, which is a force sensor of the battery swelling force measurement apparatus according to the present disclosure, to measure the swelling force of the battery cell.

The swelling force of the battery cell 10 may be changed while acting toward the first FSR 20, and this change in swelling force of the battery cell 10 may be measured by the first FSR 20.

As shown in FIG. 7, if the swelling force of the battery cell 10 is applied to the first FSR 20, the sensing plate 21 of the first FSR 20 is bent toward the sensing plate displacement space 27 of the sensing plate 21 and comes into contact with the second electrode 23, thereby causing a change in resistance.

The first FSR 20 measures the change in swelling force of the battery cell 10 as the change in resistance in this way, and outputs a resistance change signal representing the measured change in resistance to the controller 60 as an output signal.

Here, the output signal output from the first FSR 20 to the controller 60, i.e., the resistance change signal measured depending on the change in swelling force of the battery cell 10, may be distorted due to the change in temperature of the battery cell 10 to generate an error with an actual resistance change signal (i.e., a pure swelling force change signal), and therefore, the resistance change signal measured depending on the change in swelling force of the battery cell 10, which is the output signal measured by the first FSR 20, needs to be corrected.

For this purpose, the second FSR 40 measures the change in temperature of the battery cell 10 as a change in resistance, and outputs a resistance change signal representing the measured change in resistance to the controller 60.

That is, if heat generated from the battery cell 10 is transmitted to the second FSR 40 through the heat transfer plate 30, the resistance of the sensing plate 21 of the second FSR 40 changes due to the heat, and the second FSR 40 may output the resistance change signal representing the change in resistance due to the change in temperature of the battery cell 10 to the controller 60.

At this time, since the sensing plate 21, the first electrode 22, and the second electrode 23 of the second FSR 40 are maintained in a non-contact with the end plate 50, no pressure, such as external force or swelling force of the battery cell 10, is applied to the sensing plate 21 of the second FSR 40, and thus the second FSR 40 may easily measure the change in temperature of the battery cell 10 even though the second FST 40 is a force sensor.

Subsequently, the controller 60 performs correction by subtracting the resistance change signal depending on the change in temperature of the battery cell 10 measured by the second FSR 40 from the resistance change signal depending on the change in swelling force of the battery cell 10 measured by the first FSR 20.

Therefore, as a result of the correction performed by the controller 60, as shown in FIG. 9, a temperature-compensated pure swelling force compensation signal similar to the actual resistance change signal (the pure swelling force change signal) may be obtained by subtracting the resistance change signal depending on the change in temperature of the battery cell 10 measured by the second FSR 40 from the resistance change signal measured by the first FSR 20, i.e., the resistance change signal depending on the change in swelling force of the battery cell 10.

In this way, considering that the swelling force output signal measured by the first FSR 20 is distorted to generate an error with the actual swelling force due to the change in temperature of the battery cell 10, the swelling force of the battery cell 10 may always be accurately measured by compensating (correcting) the resistance change signal depending on the change in swelling force of the battery cell 10 measured by the first FSR 20 by the resistance change signal depending on the change in temperature of the battery cell 10 measured by the second FSR 40.

The present disclosure has been made in an effort to solve the above-described problems associated with the prior art, and it is an object of the present disclosure to provide a battery swelling force measurement apparatus in which at least two first force-sensing resistors (FSRs), which are force sensors, measure a change in resistance depending on the swelling force of a battery, at least two second FSRs, which are force sensors, measure a change in resistance depending on the temperature of the battery, and swelling force output signals measured by the first FSRs are compensated by output signals measured by the second FSRs so as to accurately measure the swelling force of the battery.

In one example, the present disclosure provides a battery swelling force measurement apparatus including first FSRs configured to be in close contact with both sides of a battery cell and measure a change in resistance depending on a swelling force of the battery cell, heat transfer plates configured to be in close contact with outer surfaces of the first FSRs, second FSRs configured to be in close contact with outer surfaces of the heat transfer plates and measure a change in resistance depending on a temperature of the battery cell, a pair of end plates configured to be in close contact with outer surfaces of the second FSRs and fasten the battery cell, the first FSRs, the heat transfer plates, and the second FSRs with a designated fastening pressure, and a controller configured to correct an output signal of each of the first FSRs based on an output signal of a corresponding one of the second FSRs.

Each of the first FSRs and the second FSRs may include a conductive sensing plate formed of a pressure resistant material, a first electrode provided in a structure in which a first electrode line having a predetermined length is integrally connected, and configured to be in close contact with one surface of the sensing plate, a second electrode provided in a structure in which a second electrode line having a predetermined length is integrally connected, and configured to be in close contact with a remaining surface of the sensing plate, and an insulating protective layer applied to outer surfaces of the first electrode and the first electrode line and outer surfaces of the second electrode and the second electrode line.

A support layer configured to be in non-contact with the sensing plate, the first electrode, and the second electrode and closely supported by an inner surface of each of the pair of end plates may extend from a periphery of the insulating protective layer.

A sensing plate displacement space may be defined between the sensing plate and the second electrode by stacking a ring-shaped adhesive spacer between the sensing plate and the second electrode.

A contact avoidance hole for non-contact with the sensing plate of each of the second FSRs may be formed through a corresponding one of the pair of end plates.

A guide groove may be formed on an inner surface of each of the pair of end plates to lead the electrode lines of a corresponding one of the first FSRs and a corresponding one of the second FSRs to outside.

Bolt fastening holes may be formed at respective corners of each of the pair of end plates to fasten the pair of end plates to each other with bolts.

Springs may be loaded on peripheries of the bolts to be disposed between the pair of end plates to elastically support the pair of end plates.

The controller may be configured to perform correction by subtracting a resistance change signal depending on the change in temperature of the battery cell measured by each of the second FSRs from a resistance change signal depending on the change in swelling force of the battery cell measured by a corresponding one of the first FSRs.

If a plurality of battery cells is stacked, a support block configured to support peripheries of the plurality of battery cells may be further disposed between the pair of end plates.

The support block may be provided in a structure in which a battery cell accommodation space is formed to penetrate a center of the support block from side to side, and bolt fastening holes are formed at respective corners of both surfaces of the support block to be fasten to the pair of end plates with bolts.

A guide block having guide holes configured to withdraw the electrodes lines of the first FSRs and the second FSRs to outside may be attached to a front part of the support block.

As is apparent from the above description, the present disclosure provides the following effects.

First, considering that a swelling force output signal measured by a first FSR is distorted to generate an error with an actual swelling force due to a change in temperature of a battery, the swelling force of the battery may always be accurately measured by compensating (correcting) an output signal measured by the first FSR (a change in resistance due to a change of swelling force of the battery) by an output signal measured by a second FSR (a change in resistance due to a change in temperature of the battery).

Second, battery explosions or fires may be prevented by enabling accurate real-time monitoring of the swelling force of the battery due to swelling of lithium-ion battery cells, i.e., the swelling force of the battery.

The disclosure has been described in detail with reference to preferred examples thereof. However, it will be appreciated by those skilled in the art that changes may be made in these examples without departing from the principles and spirit of the disclosure, the scope of which is defined in the appended claims and their equivalents.

What is claimed is:

1. An apparatus for monitoring battery swelling, the apparatus comprising:
a first plurality of sensors configured to be in contact with two sides of a battery cell and measure, based on a swelling force of the battery cell, a change in resistance of the battery cell;
heat transfer plates configured to be in contact with outer surfaces of the first plurality of sensors;
a second plurality of sensors configured to be in contact with outer surfaces of the heat transfer plates and measure, based on a temperature of the battery cell, a change in the resistance;
a pair of end plates configured to be in contact with outer surfaces of the second plurality of sensors and fasten, based on a designated fastening pressure, the battery cell, the first plurality of sensors, the heat transfer plates, and the second plurality of sensors; and
a controller configured to adjust, based on an output signal of a sensor of the second plurality of sensors, an output signal of a corresponding sensor of the first plurality of sensors.

2. The apparatus of claim 1, wherein each sensor of the second plurality of sensors comprises:
a conductive sensing plate formed of a pressure resistant material;
a first electrode provided in a first structure and configured to be in contact with one surface of the conductive sensing plate, wherein a first electrode line having a first predetermined length is integrally connected in the first structure;
a second electrode provided in a second structure and configured to be in contact with a remaining surface of the conductive sensing plate, wherein a second electrode line having a second predetermined length is integrally connected in the second structure; and
an insulating protective layer applied to:
outer surfaces of the first electrode and the first electrode line, and
outer surfaces of the second electrode and the second electrode line.

3. The apparatus of claim 2, wherein a support layer configured to be in non-contact with the conductive sensing plate, the first electrode, and the second electrode, wherein the support layer is supported by an inner surface of each of the pair of end plates, and wherein the support layer extends from a periphery of the insulating protective layer.

4. The apparatus of claim 2, wherein a sensing plate displacement space is configured to be between the conductive sensing plate and the second electrode by stacking a ring-shaped adhesive spacer between the conductive sensing plate and the second electrode.

5. The apparatus of claim 2, wherein a contact avoidance hole for non-contact with the conductive sensing plate of each of the second plurality of sensors is formed through a corresponding one of the pair of end plates.

6. The apparatus of claim 1, wherein a guide groove is formed on an inner surface of each of the pair of end plates to:
guide first electrode lines of a corresponding sensor of the first plurality of sensors to outside of the pair of end plates, and
guide second electrode lines of a corresponding sensor of the second plurality of sensors to outside of the pair of end plates.

7. The apparatus of claim 1, wherein bolt fastening holes are formed at respective corners of each of the pair of end plates to fasten the pair of end plates to each other with bolts.

8. The apparatus of claim 7, wherein springs are loaded on peripheries of the bolts and disposed between the pair of end plates to elastically support the pair of end plates.

9. The apparatus of claim 1, wherein the controller is configured to adjust, based on a difference between a first resistance change signal and a second resistance change signal, the output signal of the corresponding sensor of the first plurality of sensors, wherein the second resistance change signal is based on a change in the temperature of the battery cell, and wherein the first resistance change signal is based on a change in the swelling force of the battery cell measured by the corresponding sensor of the first plurality of sensors.

10. The apparatus of claim 1, wherein, a support block is configured to support, based on a plurality of battery cells being stacked, peripheries of the plurality of battery cells, and wherein the support block is disposed between the pair of end plates.

11. The apparatus of claim 10, wherein the support block is configured with a battery cell accommodation space that extends through a center of the support block from side to side, wherein bolt fastening holes are formed at respective corners of surfaces of the support block, and wherein the support block is fastened to the pair of end plates with bolts placed in the bolt fastening holes.

12. The apparatus of claim 11, wherein a guide block having guide holes is configured to guide first electrode lines of the first plurality of sensors to outside of the pair of end plates and guide second electrode lines of the second plurality of sensors to outside of the pair of end plates, and wherein the guide block is attached to a front part of the support block.

13. A method performed by an apparatus for monitoring battery swelling, the method comprising:
based on a designated fastening pressure, fastening, by a pair of end plates of the apparatus, a battery cell, a first plurality of sensors of the apparatus, heat transfer plates of the apparatus, and a second plurality of sensors of the apparatus; and
based on the fastening and a swelling force of the battery cell, measuring, by the first plurality of sensors, a first change in resistance of the battery cell;
measuring, by the second plurality of sensors and based on a temperature of the battery cell, a second change in the resistance, wherein the second plurality of sensors are in contact with outer surfaces of the heat transfer plates that are in contact with outer surfaces of the first plurality of sensors; and
adjusting, by a controller of the apparatus, based on the first change and the second change, an output signal of a sensor of the first plurality of sensors.

14. The method according to claim 13, wherein the fastening comprises:
placing bolts in bolt fastening holes formed at respective corners of each of the pair of end plates; and
elastically supporting, by springs loaded on peripheries of the bolts and disposed between the pair of end plates, the pair of end plates.

15. The method according to claim 13, wherein the adjusting the output signal of the sensor of the first plurality of sensors comprises:
subtracting the second change from the first change; and
adjusting, based on the subtracting, the output signal of the sensor of the first plurality of sensors.

16. The method according to claim 13, further comprising:
transferring, by the heat transfer plates, heat generated from a surface of the battery cell to the second plurality of sensors.

17. The method according to claim 13, wherein the pair of end plates comprise contact avoidance holes so that contact surface areas between the second plurality of sensors and the pair of end plates are reduced.

18. The method according to claim 13, wherein the first plurality of sensors and the second plurality of sensors are force sensitive resistors configured as thin-films attachable to surfaces of the battery cell.

19. The method according to claim 13, further comprising:
performing, based on the output signal of the sensor of the first plurality of sensors, real-time monitoring of the battery swelling.

20. The method according to claim 13, further comprising:
displaying, by the controller, at least one of:
the output signal of the sensor of the first plurality of sensors, or
an output signal of a sensor of the second plurality of sensors.
